(19) United States
(12) Patent Application Publication
(10) Pub. No.: US 2009/0053883 A1
(43) Pub. Date: Feb. 26, 2009

(54) METHOD OF SETTING A WORK FUNCTION OF A FULLY SILICIDED SEMICONDUCTOR DEVICE, AND RELATED DEVICE

(75) Inventors: Luigi COLOMBO, Dallas, TX (US); Mark R. VISOKAY, Wappingers Falls, NY (US); James J. CHAMBERS, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/844,625

(22) Filed: Aug. 24, 2007

(51) Int. Cl. H01L 27/092; H01L 21/3205

(52) U.S. Cl. 438/592; 257/374; 257/E27.062; 257/E21.294

(57) ABSTRACT

A method of setting a work function of a fully silicided semiconductor device, and related device. At least some of the illustrative embodiments are methods comprising forming a gate stack over a semiconductor substrate (the gate stack comprising a dielectric layer, a silicide layer on the dielectric layer that defines a metal-dielectric layer interface, and a polysilicon layer on the silicide layer), depositing a metal layer over the gate stack, annealing to induce a reaction between the polysilicon layer and the metal layer, and delivering a work function-setting dopant to the metal-dielectric layer interface by way of the reaction.

### BACKGROUND

Electronic devices are continually getting smaller, faster, and using less power, while simultaneously being able to support and perform a greater number of increasingly complex and sophisticated functions. One reason for these trends is an ever increasing demand for small, portable and multifunctional electronic devices. For example, cellular phones, personal computing devices, and personal audio devices (e.g., MP3 players) are in great demand in the consumer market. Such electronic devices rely on a limited power source (e.g., batteries) while providing ever-increasing processing capabilities and storage capacity.

Accordingly, there is a continuing trend in the semiconductor industry to manufacture low-cost, high-performance, and low-power integrated circuits (ICs). These goals have been achieved in great part by scaling down the dimensions of semiconductor ICs and thus increasing device and circuit densities. Achieving higher densities calls for smaller feature sizes, smaller separations between features and layers, and more precise feature shapes. The scaling down of IC dimensions can facilitate faster circuit performance (e.g., faster switching speeds) and can lead to higher effective yield in IC fabrication processes by providing (i.e., “packing”) more circuits on a semiconductor die and/or more die on a semiconductor wafer.

A fundamental building block of semiconductor ICs is the metal-oxide semiconductor (MOS) transistor. FIG. 1 illustrates a cross-section of a MOS transistor 100. The transistor 100 is fabricated on a semiconductor substrate 110 and comprises a gate stack 120. The gate stack 120 comprises a gate dielectric 130 (e.g., silicon dioxide) and a gate electrode 140 (e.g., polysilicon) on the gate dielectric 130. The transistor 100 also comprises a source region 150 and a drain region 160 each formed within the semiconductor substrate 110. A channel 170 is defined between the source and drain regions 150, 160, under the gate dielectric 130, and within the semiconductor substrate 110. The channel 170 has an associated channel length “L” and an associated channel width “W”. When a bias voltage greater than a threshold voltage (Vt) (i.e., turn-on voltage) for the transistor 100 is applied to the gate electrode 140 along with a concurrently applied bias voltage between the source and drain regions 150, 160, an electric current (e.g., a transistor drive current) flows between the source and drain regions 150, 160 through the channel 170. The amount of drive current developed for a given bias voltage (e.g., applied to the gate electrode 140 or between the source and drain regions 150, 160) is a function of, among others, the width-to-length ratio (W/L) of the channel 170.

MOS transistors have become cheaper, faster, and less power-hungry with each new technology generation as the physical dimensions and applied voltages have been scaled down. To date, most transistor scaling has been achieved by thinning the gate dielectric 130 or reducing the channel length “L”. However, as transistor scaling moves into the nanometer-scale regime, scaling the gate dielectric 130 thickness or the channel length “L” is not sufficient as new phenomenon appear (e.g., leakage current flowing through the gate dielectric 130, polysilicon gate electrode depletion effects (“poly-depletion”), and contact resistance effects), which reduce the transistor drive current. The poly-depletion effect is characterized by a polysilicon gate electrode 140 that is no longer fully conductive and contributes an additional capacitance (in series) between the gate electrode 140 and the silicon substrate 110, resulting in reduced transistor drive current. Gate dielectrics having a high dielectric constant (“high-K” gate dielectrics) have been introduced in an effort to improve transistor drive current without increasing the leakage current through the gate dielectric 130. However, high-K gate dielectrics face reliability and compatibility issues with polysilicon gate electrodes such as poor work function control, which results in, for example, transistors having an unsuitable threshold voltage (V_{T}). For high-K and other gate dielectric materials such as silicon dioxide, polysilicon gate electrodes become problematic with scaling due to the poly-depletion effect and contact resistance problems.

### SUMMARY

The problems noted above are solved in large part by a method of setting a work function of a fully silicided semiconductor device, and related device. At least some of the illustrative embodiments are methods comprising forming a gate stack over a semiconductor substrate (the gate stack comprising a dielectric layer, a silicide layer on the dielectric layer that defines a metal-dielectric layer interface, and a polysilicon layer on the silicide layer), depositing a metal layer over the gate stack, annealing to induce a reaction between the polysilicon layer and the metal layer, and delivering a work function-setting dopant to the metal-dielectric layer interface by way of the reaction.

Other illustrative embodiments are methods comprising forming a PMOS gate stack over a semiconductor substrate (the PMOS gate stack comprising a first dielectric layer, a first silicide layer on the first dielectric layer that defines a first metal-dielectric layer interface, and a first polysilicon layer on the first silicide layer), forming an NMOS gate stack over a semiconductor substrate (the NMOS gate stack comprising a second dielectric layer, a second silicide layer on the second dielectric layer that defines a second metal-dielectric layer interface, and a second polysilicon layer on the second silicide layer), depositing a metal layer over both the PMOS gate stack and the NMOS gate stack, annealing to induce a reaction between the first polysilicon layer and the metal layer and between the second polysilicon layer and the metal layer, delivering a first work function-setting dopant to the first metal-dielectric layer interface by way of the reaction, and delivering a second work function-setting dopant to the second metal-dielectric layer interface by way of the reaction.

Yet other illustrative embodiments are semiconductor devices comprising a substrate comprising a P-type active area, an isolation structure abutting the P-type active area, an N-type active area abutting the isolation structure, a PMOS gate stack on the P-type active area (the PMOS gate stack comprising a first dielectric layer, a first silicide layer on the first dielectric layer that defines a first metal-dielectric layer interface, and a first polysilicon layer on the first silicide layer), an NMOS gate stack on the N-type active area (the NMOS gate stack comprising a second dielectric layer, a second silicide layer on the second dielectric layer that defines a second metal-dielectric layer interface, and a second polysilicon layer on the second silicide layer), a metal layer on the PMOS gate stack and on the NMOS gate stack (the metal layer is configured to react with each of the first polysilicon layer and the second polysilicon layer), a first work function-setting dopant within the PMOS gate stack, and a second work function-setting dopant within the NMOS gate stack. The first work function-setting dopant is delivered to first metal-dielectric layer interface by way of the reaction. The second work function-setting dopant is delivered to the second metal-dielectric layer interface by way of the reaction.

### BRIEF DESCRIPTION OF THE DRAWINGS

For a more detailed description of the various embodiments, reference will now be made to the accompanying drawings, wherein:

FIG. 1 shows a perspective view of a MOS transistor;

FIG. 2 shows a cross sectional view illustrating the formation of a MOS transistor after formation of a metal layer and a first polysilicon layer on the metal layer;

FIG. 3 shows a cross sectional view illustrating the formation of a MOS transistor after formation of a silicide layer;

FIG. 4 shows a cross sectional view illustrating the formation of a MOS transistor after formation of a second polysilicon layer;

FIG. 5 shows a cross sectional view illustrating the formation of a MOS transistor after formation of a PMOS transistor and an NMOS transistor;

FIG. 6 shows a cross sectional view illustrating the formation of a MOS transistor during an NMOS implant;

FIG. 7 shows a cross sectional view illustrating the formation of a MOS transistor during a PMOS implant;

FIG. 8 shows a cross sectional view illustrating the formation of a MOS transistor after silicidation of a PMOS polysilicon layer and an NMOS polysilicon layer;

FIG. 9 shows a cross sectional view illustrating the formation of a MOS transistor after removal of any metal remaining after the silicidation;

FIG. 10 shows a cross sectional view illustrating the formation of a MOS transistor during a blanket implant according to some embodiments;

FIG. 11 shows a cross sectional view illustrating the formation of a MOS transistor during a blanket implant according to alternative embodiments;

FIG. 12 shows a cross sectional view illustrating the formation of a MOS transistor during an NMOS implant according to alternative embodiments; and

FIG. 13 shows a cross sectional view illustrating the formation of a MOS transistor during a PMOS implant according to alternative embodiments.

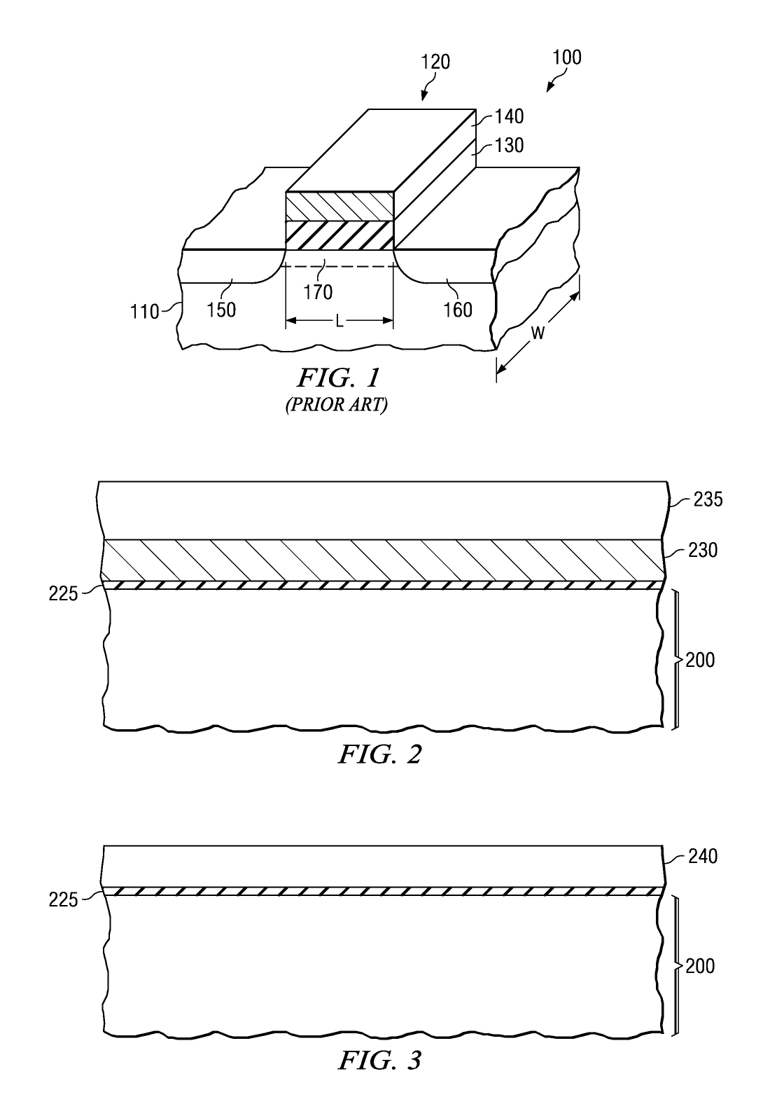

### NOTATION AND NOMENCLATURE

Certain terms are used throughout the description and claims that follow to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct connection. Thus, if a first device couples to a second device, that connection may be through a direct connection, or through an indirect connection via other devices and connections.

The term “active area” means a region where a semiconductor device is formed within and/or on a semiconductor substrate, and where the active area does not comprise isolation structures, such as shallow trench isolation (STI) structures or field oxide (FOX) regions.

Unless otherwise stated, when a layer is said to be “deposited over the substrate” or “formed over the substrate”, it means that the layer is deposited or formed over any topography that already exists on the substrate.

The term “thermal budget” is used to define an amount of thermal energy transferred to a semiconductor wafer (e.g., during a high-temperature process) and is given as a product of temperature (e.g., in degrees Kelvin) and time (e.g., in seconds). Low thermal budget processes are preferred, for example, to prevent dopant redistribution or electro-migration.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment. Also, layers and/or elements depicted herein are illustrated with particular dimensions and/or orientations relative to one another for purposes of simplicity and ease of understanding, and actual dimensions and/or orientations of the layers and/or elements may differ substantially from that illustrated herein.

The subject matter disclosed herein is directed to methods associated with construction of a semiconductor device, such as a metal-oxide semiconductor (MOS) transistor. A semiconductor is a material (e.g., silicon or germanium) having properties somewhere between a conductor and an insulator. By adding impurities (e.g., by a process known as “doping”), a semiconductor can be classified as being electron-rich (N-type) or electron-poor (P-type). Through a series of semiconductor processing techniques (e.g., deposition, photolithography, etching, ion implantation), semiconductor materials are used to make semiconductor devices (e.g., transistors) which are in turn used to make integrated circuits (ICs). Moreover, N-channel MOS transistors (NMOS) and P-channel MOS (PMOS) transistors are often used together to form complementary metal-oxide semiconductor (CMOS) ICs.

Metallic gate electrodes in semiconductor CMOS ICs overcome electrostatic and transport issues (e.g., poly-depletion, threshold voltage control, and contact resistance) associated with scaled-down polysilicon gate electrodes. In particular, the various embodiments provide a dual-metal gate system having a first metal with a work function near the conduction band of silicon (e.g., about 4 electron-volts (eV)) for NMOS transistors and a second metal with a work function near the valence band of silicon (e.g., about 5 eV) for PMOS transistors. The metals with the recited work functions are advantageous because they enable fabrication of low threshold voltage (Vt) transistors. Integration of metal gate electrodes into a CMOS process flow can be performed according to either a metal gate first (MGF) or a metal gate last (MGL) approach.

In MGF integration schemes the metal gate electrodes are subjected to high thermal budget processing (e.g., a source/drain activation anneal), and thus the stability of the metal-dielectric interface becomes an issue. In particular, a metal gate electrode (e.g., in a MGF approach) may have a desirable work function initially after formation, but exposure to high thermal budget processing can cause an undesirable shift in the work function, resulting in a shift in transistor V_{T} and a degradation of transistor drive current. Thus, it is desirable to provide a metal gate electrode integration process that is robust with regard to subsequent thermal processing, for example, by using a metal that is stable at high temperatures.

MGL integration schemes provide one alternative approach to mitigate problems associated with high temperature processing by introducing the metal gate after high thermal budget processing (e.g., the source/drain activation anneal) is complete. For example, integration of a metal gate electrode can be done by way of a fully silicided (FUSI) process flow. Silicidation of a polysilicon gate electrode involves depositing a layer of metal (e.g., Nickel) over the polysilicon gate and annealing to induce a reaction between the metal and the polysilicon gate. During the annealing process, the deposited layer of metal diffuses into the polysilicon gate and reacts to form a metal silicide (e.g., nickel silicide). In a FUSI process flow, the deposited layer of metal diffuses into, and reacts with, the entire polysilicon gate to form a “fully” silicided metal gate, as opposed to diffusing into, and reacting with, less than the entire polysilicon gate to form a partially silicided metal gate, where pockets of unreacted polysilicon (or an entire unreacted polysilicon layer) remain within the gate electrode. However, even in a FUSI process flow, it is possible that pockets of unreacted polysilicon remain, causing an undesirable shift in transistor inversion layer thickness and a corresponding degradation of the transistor drive current. Thus, it is desirable to keep the polysilicon away from the dielectric interface to avoid possible degradation due to unreacted polysilicon. In some embodiments, the polysilicon gate is doped prior to silicidation by way of a FUSI process flow, where the doping is used to set the work function of the subsequently silicided gate. However, it can be difficult to tune the work function of the silicided gate by way of a FUSI process flow (and especially difficult to tune the work function to the silicon conduction and valence band edges).

While MGL approaches can mitigate some of the problems associated with exposure to high thermal budget processing, it is possible (e.g., in a FUSI process flow) that after the polysilicon gate has fully reacted with the metal (e.g., nickel), the metal reaches the dielectric interface, and reacts with, or diffuses through the gate dielectric, causing a punch-through defect that effectively destroys transistor operation. It is also therefore desirable to keep the reacting metal (e.g., nickel) away from the dielectric interface. Embodiments described herein provide a method of integrating a metallic gate electrode into a CMOS process flow where a metal (that is stable at high temperatures) is used to cap the gate dielectric to protect the metal-dielectric interface, and where subsequent FUSI processing is used to deliver work function-setting dopants to the metal-dielectric interface. For purposes of this disclosure, the term “work function-setting dopants” is used to refer to any of a plurality of high or low work function metals (or other high or low work function elements) that are delivered to the metal-dielectric interface and are used to set the work function of the metal gate electrode. In particular, a high work function metal delivered to the metal-dielectric interface tends to increase the work function of the metal gate electrode, and a low work function metal delivered to the metal-dielectric interface tends to decrease the work function of the metal gate electrode.

Referring to FIG. 2, a dielectric layer 225 is formed over a substrate 200. In some embodiments, the substrate 200 comprises, for example, a P-type single crystal silicon substrate that may be formed, for example, by epitaxial growth. In other embodiments, the substrate 200 comprises for example, a silicon germanium (SiGe) substrate or a silicon-on-insulator (SOI) substrate. The dielectric layer 225 comprises a non-conductive material (e.g., a silicon oxide (i.e., SiO₂), a silicon oxynitride, or a high dielectric constant (“high-K”) material such as a hafnium-based metal-oxide or hafnium-based silicate such as a nitrided hafnium silicate (HfSiON)). Depending on the material used for the dielectric layer 225, the dielectric layer 225 can be formed by a variety of techniques (e.g., thermal oxidation, thermal oxidation followed by a plurality of nitridation techniques, atomic layer deposition (ALD), or chemical vapor deposition (CVD)). A metal layer 230 is then formed over the dielectric layer 225. The metal layer 230 comprises a conductive material (e.g., tungsten (W) or molybdenum (Mo)). The metal layer 230 is formed, for example, by a physical vapor deposition (PVD) method such as sputter deposition, which results in a high purity layer. Moreover, the metal layer 230 has high-temperature stability as compared to, for example, nickel. Thus, the metal layer 230 protects the dielectric layer 225 from subsequent high thermal budget processing, or other subsequent processing (discussed below). In addition, the metal layer 230 comprises sufficient grain boundaries such that work function-setting dopants can be effectively diffused through the metal layer 230 to the metal-dielectric interface. In some embodiments, the metal layer 230 has a thickness of about 1 nanometer to about 20 nanometers. Thereafter, a polysilicon layer 235 is formed over the metal layer 230. The polysilicon layer 235 is formed, for example, by using a low-pressure chemical vapor deposition (LPCVD) process. In some embodiments, the polysilicon layer 235 has a thickness of about 1 nanometer to about 40 nanometers.

As shown in FIG. 3, an anneal is performed to induce a reaction between the metal layer 230 (FIG. 2) and the polysilicon layer 235 (FIG. 2), thus forming a silicide layer 240, which serves as the metal gate electrode for both NMOS and PMOS transistors. In some embodiments, an reacted portion (not shown) of the polysilicon layer 235 (FIG. 2) remains after formation of the silicide layer 240. The work function of the metal gate electrode for each of the NMOS and PMOS transistors is modified and/or set during subsequent processing by the work-function setting dopants (discussed below). In some embodiments, the silicide layer 240 comprises tungsten silicide (WSi₂) or molybdenum disilicide (MoSi₂). In other embodiments, the silicide layer 240 comprises a W/WSi₂ stack, a Mo/MoSi₂ stack, or crystalline TaN which can result, for example, from less than all of the metal layer 230 (FIG. 2) reacting during the anneal. In yet other embodiments, the silicide layer 240 comprises an alternative refractory metal silicide. In some illustrative embodiments, the anneal is not performed to induce the reaction between the metal layer 230 (FIG. 2) and the polysilicon layer 235 (FIG. 2), or the metal layer 230 is chosen such that it does not react with silicon, thus the metal layer 230 serves as the metal gate electrode for both NMOS and PMOS transistors.

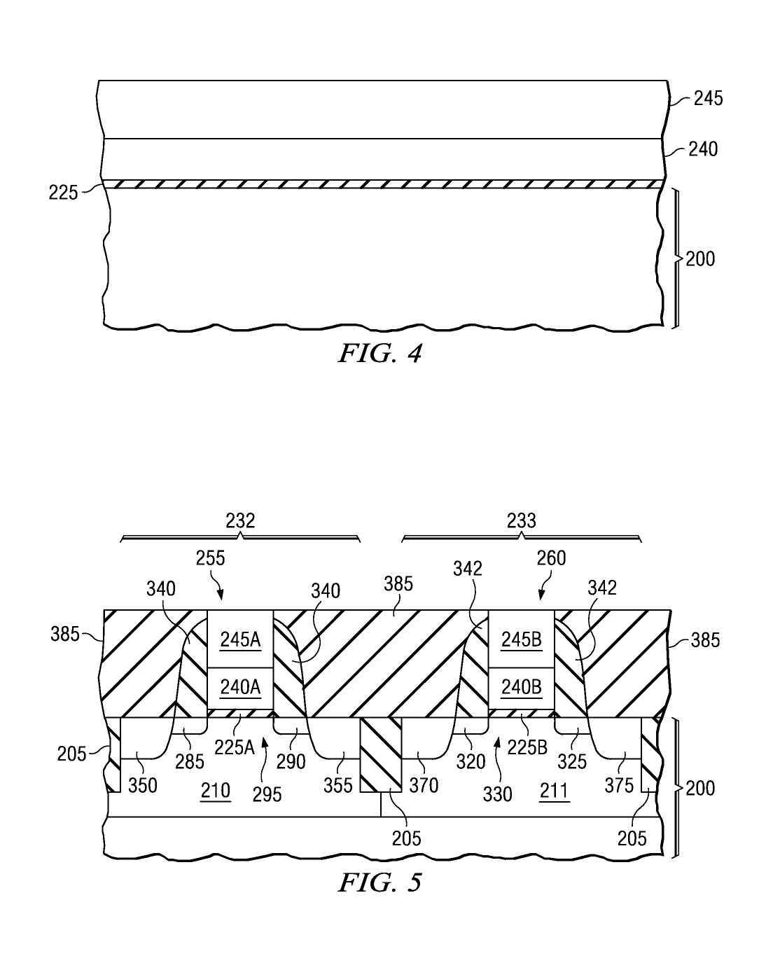

Referring to FIG. 4, after formation of the silicide layer 240, any unreacted portion (if any) of the polysilicon layer 235 (FIG. 2) is removed and a polysilicon layer 245 is deposited over the silicide layer 240. The polysilicon layer 245 is formed, for example, by using an LPCVD process, and has a thickness of about 10 nanometers to about 80 nanometers. Any unreacted portion (if any) of the polysilicon layer 235 is removed prior to formation of the polysilicon layer 245 because such unreacted portion of the polysilicon layer will often have voids that formed during prior processing.

Referring to FIG. 5, a PMOS transistor is formed in active area 232, and an NMOS transistor is formed in active area 233, by way of a sequence of various semiconductor processing techniques (e.g., deposition, pattering, etching, ion implantation, etc.). In particular, isolation structures 205 are formed within a substrate 200 in order to define the active area 232 and active area 233, and to electrically isolate neighboring devices (e.g., transistors) from one another. The isolation structures 205 can be formed, for example, by a shallow trench isolation (STI) process. A well 210 and a well 211 are also formed within the substrate 200, for example, by performing an ion implantation into the substrate 200 followed by a high-temperature anneal. Each of the wells 210, 211 are doped with N-type dopants (e.g., phosphorous or arsenic) or P-type dopants (e.g., boron) depending on the type of transistor (NMOS or PMOS) to be formed within each of the active areas 232, 233. For purposes of this disclosure, the well 210 is doped with an N-type dopant (thus, a PMOS transistor is formed within the active area 232, and the active area 232 may be equivalently referred to as a PMOS active area 232), and the well 211 is doped with an P-type dopant (thus, an NMOS transistor is formed within the active area 233, and the active area 233 may be equivalently referred to as an NMOS active area 233).

As shown in FIG. 5, the dielectric layer 225 (FIG. 4), the silicide layer 240 (FIG. 4), and the polysilicon layer 245 (FIG. 4) have been patterned and etched to form a PMOS gate stack 255. Thus, the PMOS gate stack 255 comprises a dielectric layer 225A, a silicide layer 240A, and a polysilicon layer 245A. The dielectric layer 225 (FIG. 4), the silicide layer 240 (FIG. 4), and the polysilicon layer 245 (FIG. 4) are also patterned and etched to form an NMOS gate stack 260. Thus, the NMOS gate stack 260 comprises a dielectric layer 225B, a silicide layer 240B, and a polysilicon layer 245B. During subsequent processing, each of the polysilicon layer 245A and the polysilicon layer 245B are silicided using a FUSI process flow, and work function-setting dopants are delivered to each of the dielectric layer 225A/silicide layer 240A interface and the dielectric layer 225B/silicide layer 240B interface in order to set the work function for each of the PMOS and NMOS transistor metal gate electrodes. For each of the PMOS gate stack 255 and the NMOS gate stack 260, the layers shown in FIG. 4 are patterned simultaneously by way of a light sensitive layer (e.g., photoresist), and various (dry or wet) etchants can be used to remove each of the layers in sequence to form each of the PMOS gate stack 255 and the NMOS gate stack 260, using the patterned light sensitive layer as a mask. After etching of the layers to form the PMOS gate stack 255, the light sensitive layer, used for patterning of the layers of the PMOS gate stack 255, is removed (e.g., by an “ashing” process). Similarly, after etching of the layers to form the NMOS gate stack 260, the light sensitive layer, used for patterning of the layers of the NMOS gate stack 260, is removed (e.g., by an “ashing” process).

Still referring to FIG. 5, after forming the PMOS gate stack 255 and the NMOS gate stack 260, a lightly doped source region 285 and a lightly doped drain region 290 are created (e.g., by way of masking the NMOS active are 233 and performing an ion implantation into the PMOS active area 232). In some embodiments, a thin conformal oxide or nitride layer may be deposited over the PMOS gate stack 255 prior to the ion implantation in order to protect sidewalls of the PMOS gate stack 255. The lightly doped source and drain regions 285, 290 may be equivalently referred to as PMOS source and drain extension regions. A channel 295 is defined between the lightly doped source region 285 and the lightly doped drain region 290, under the gate dielectric 225A, and within the substrate 200. The channel 295 has an associated channel length “L” and an associated channel width “W”. In some embodiments, a thermal process, such as a rapid thermal anneal, is performed to activate the dopants within the lightly doped source and drain regions 285, 290.

Similarly, a lightly doped source region 320 and a lightly doped drain region 325 are created (e.g., by way of masking the PMOS active area 232 and performing an ion implantation into the NMOS active area 233). In some embodiments, a thin conformal oxide or nitride layer may be deposited over the NMOS gate stack 260 prior to the ion implantation in order to protect sidewalls of the NMOS gate stack 260. The lightly doped source and drain regions 320, 325 may be equivalently referred to as NMOS source and drain extension regions. A channel 330 is defined between the lightly doped source region 320 and the lightly doped drain region 325, under the gate dielectric 225B, and within the substrate 200. The channel 330 has an associated channel length “L” and an associated channel width “W”. In some embodiments, a thermal process, such as a rapid thermal anneal, is performed to activate the dopants within the lightly doped source and drain regions 320, 325.

A spacer 340 is formed on each sidewall of the PMOS gate stack 255 and a spacer 342 is formed on each sidewall of the NMOS gate stack 260. Each spacer 340, 342 comprises an insulating material such as an oxide and/or nitride based material. In some embodiments, the spacers 340, 342 comprise a bistertiary-butylaminosilane (BTBAS) silicon nitride layer. The spacers 340, 342 are formed by depositing one or more layers of such material(s) over the substrate 200 in a conformal manner, followed by an anisotropic etch thereof, thereby removing spacer material from the top of the PMOS gate stack 255 and the substrate 200 (or from the top of the NMOS gate stack 260 and the substrate), while leaving the spacers 340 (or the spacers 342) on each of the sidewalls of the PMOS gate stack 255 (or the NMOS gate stack 260). Thereafter, a source region 350 and a drain region 355 are created (e.g., by way of masking the NMOS active area 233 and performing an ion implantation into the PMOS active area 232). The spacers 340 serve to protect the sidewalls of the PMOS gate stack 255. In some embodiments, a thermal process, such as a rapid thermal anneal, is performed to activate the dopants within the source and drain regions 350, 355.

Similarly, a source region 370 and a drain region 375 are created (e.g., by way of masking the PMOS active area 232 and performing an ion implantation into the NMOS active area 233). The spacers 342 serve to protect the sidewalls of the NMOS gate stack 260. In some embodiments, a thermal process, such as a rapid thermal anneal, is performed to activate the dopants within the source and drain regions 370, 375.

In some embodiments, silicidation of the source and drain regions 350, 355 is performed separately from silicidation of the polysilicon layer 245A, and silicidation of the source and drain regions 370, 375 is performed separately from silicidation of the polysilicon layer 245B. For example, in some embodiments, silicidation of each of the source and drain regions 350, 355, 370, 375 is performed before processing of each of the PMOS gate stack 255 and the NMOS gate stack 260 is substantially complete (i.e., before delivery of work function-setting dopants by way of silicidation of the polysilicon layer 245A and the polysilicon layer 245B), and before deposition of an oxide layer 385. In other embodiments, silicidation of each of the source and drain regions 350, 355, 370, 375 is performed after processing of each of the PMOS gate stack 255 and the NMOS gate stack 260 is substantially complete. In some exemplary embodiments where the silicidation of the source and drain regions 350, 355, 370, 375 is performed before processing of the PMOS gate stack 255 and the NMOS gate stack 260 is substantially complete, each of the source and drain regions 350, 355, 370, 375 comprises a material with high thermal stability (e.g., nickel-platinum silicide (NiPtSi)) that is able to withstand subsequent thermal processing (e.g., of the PMOS gate stack 255 and the NMOS gate stack 260). In addition, the metal used to silicide each of the source and drain regions 350, 355, the source and drain regions 370, 375, and each of the polysilicon layer 245A and the polysilicon layer 245B can be separately and independently selected depending on the transistor type (NMOS or PMOS) and the desired process integration. As an illustrative example, erbium silicide (ErSi₂) may be used for the NMOS source and drain regions 370, 375, platinum silicide (PtSi) may be used for the PMOS source and drain regions 350, 355, and nickel silicide (NiSi) may be used for each of the polysilicon layer 245A and the polysilicon layer 245B.

As shown in FIG. 5, the oxide layer 385 is formed over the substrate 200. The oxide layer 385 may comprise, for example, a layer of tetraethyl orthosilicate (TEOS). In some embodiments, the oxide layer 385 before planarization has a thickness of about 100 nanometers to about 400 nanometers. The planarization of the oxide layer 385 is performed by way of a chemical mechanical polishing (CMP) process, whereby the oxide layer 385 is mechanically polished by a polishing pad while a chemical slurry containing abrasives chemically reacts with the oxide layer 385 to increase the removal rate of the oxide layer 385. Planarization by way of a CMP process is used, for example, to bring an entire topography within a depth of field (DOF) of a given photolithography system. The oxide layer 385 is polished until the polysilicon layer 245A is exposed over the PMOS gate stack 255 and the polysilicon layer 245B is exposed over the NMOS gate stack 260. In some embodiments, the polishing may also expose the spacers 340, 342. In other embodiments, a protective layer (e.g., a silicon nitride layer) is formed prior to the oxide layer 385 and in a conformal manner over the substrate 200, for example, to protect the source and drain regions 350, 355, 370, 375, and to protect the isolation structures 205. In some embodiments, after the CMP process, an acid (e.g., hydrofluoric acid (HF)) is used to etch (i.e., to clean) the top of each of the exposed polysilicon layers 245A, 245B so that a subsequently formed silicide layer will be of a high quality.

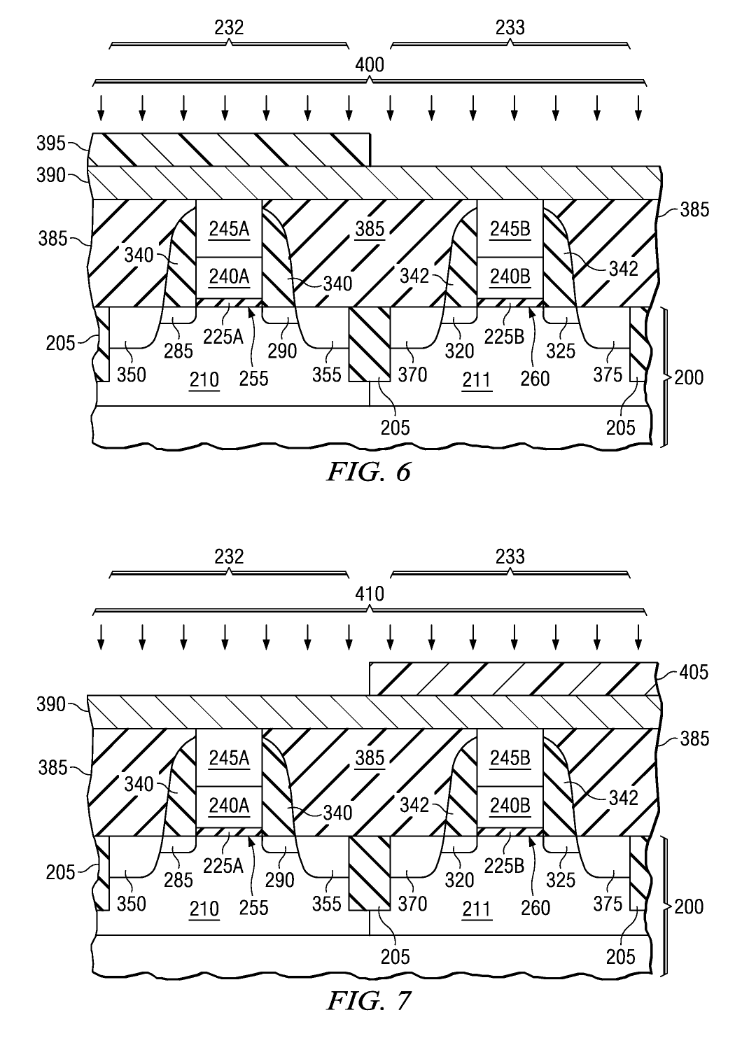

Referring to FIG. 6, a metal layer 390 (e.g., nickel) is formed over the substrate 200 as a precursor to silicidation of the polysilicon layers 245A, 245B. In some embodiments, the metal layer 390 is formed by a PVD technique such as sputtering. After formation of the metal layer 390, a light sensitive layer 395 (e.g., photoresist) is deposited on the metal layer 390 (e.g., by spin-coating), patterned using a mask (e.g., an N-type mask), and developed. Processing of the light sensitive layer 395 results in removal of the light sensitive layer 395 over the NMOS active area 233. Thereafter, an ion implantation 400 is performed (using a particular dose of an N-type work function-setting dopant). In some embodiments, the N-type work function-setting dopant comprises a low work function element such as one or more selected from the group: titanium (Ti); zirconium (Zr); hafnium (Hf); tantalum (Ta); lanthanum (La); yttrium (Y); cerium (Ce); praseodymium (Pr); neodymium (Nd); promethium (Pm); samarium (Sm); europium (Eu); gadolinium (Gd); terbium (Tb); dysprosium (Dy); holmium (Ho); erbium (Er); thulium (Tm); ytterbium (Yb); phosphorous (P); arsenic (As); or antimony (Sb). In other embodiments, the N-type work function-setting dopant comprises an alternative low work function element. The ion implantation 400 is performed (at a particular implant energy) into the NMOS active area 233 (while the light sensitive layer 395 protects the PMOS active area 232 from the ion implantation 400). In particular, the implant energy is selected such that the peak of the implanted dose of the N-type work function-setting dopant will lie within the polysilicon layer 245B, the metal layer 390 (only in the exposed NMOS active area 233), or within a combination of both the polysilicon layer 245B and the metal layer 390. In some embodiments, the ion implantation 400 is performed into the NMOS active area 233 (while masking the PMOS active area 232) prior to forming the metal layer 390. The light sensitive layer 395 is then removed (e.g., by an “ashing” process).

As shown in FIG. 7, a light sensitive layer 405 (e.g., photoresist) is deposited on the metal layer 390 (e.g., by spin-coating), patterned using a mask (e.g., a P-type mask), and developed. Processing of the light sensitive layer 405 results in removal of the light sensitive layer 405 over the PMOS active area 232. Thereafter, an ion implantation 410 is performed (using a particular dose of a P-type work function-setting dopant). In some embodiments, the P-type work function-setting dopant comprises a high work function element such as one or more selected from the group: platinum (Pt); ruthenium (Ru); rhenium (Re); rhodium (Rh); or iridium (Ir). In other embodiments, the P-type work function-setting dopant comprises an alternative high work function element. The ion implantation 410 is performed (at a particular implant energy) into the PMOS active area 232 (while the light sensitive layer 405 protects the NMOS active area 233 from the ion implantation 410). In particular, the implant energy is selected such that the peak of the implanted dose of the P-type work function-setting dopant will lie within the polysilicon layer 245A, the metal layer 390 (only in the exposed PMOS active area 232), or within a combination of both the polysilicon layer 245A and the metal layer 390. In some embodiments, the ion implantation 410 is performed into the PMOS active area 232 (while masking the NMOS active area 233) prior to forming the metal layer 390. The light sensitive layer 405 is then removed (e.g., by an “ashing” process).

In some exemplary embodiments, a blanket ion implantation is performed into both the PMOS active area 232 and the NMOS active area 233 prior to forming the metal layer 390. In yet other embodiments, a blanket ion implantation is performed into both the PMOS active area 232 and the NMOS active area after forming the metal layer 390. For embodiments where a blanket ion implantation is performed, a subsequent masked ion implantation may be performed into either of the PMOS active area 232 or the NMOS active area 233, where the masked ion implantation dopant and the blanket ion implantation dopant each contribute to the work function of the gate electrode. Thus, each of the masked ion implantation dopant and the blanket ion implantation dopant are selected to balance each other, such that the NMOS work function remains low (e.g., about 4 eV) and the PMOS work function remains high (e.g., about 5 eV).

Instead of introducing a high or low work function dopant by way of ion implantation (as discussed above), some illustrative embodiments introduce the high or low work function dopant by way of an alloy deposition (and subsequent FUSI processing). As one particular example, the metal layer 390 can be replaced by a metal alloy (e.g., a PtNi alloy), comprising a high work function element. A high work function element is appropriate for PMOS work function setting; however, a subsequent masked ion implantation into the NMOS active area 233 of a low work function element is combined with the already deposited high work function metal alloy, such that the resultant NMOS work function (after FUSI processing) remains low (e.g., about 4 eV). In some embodiments, the masked ion implantation into the NMOS active area 233 is performed prior to the high work function metal alloy deposition. In a similar manner, in other embodiments, the metal layer 390 can be replaced by a metal alloy, comprising a low work function element, deposited over the substrate 200. A low work function element is appropriate for NMOS work function setting; however, a subsequent masked ion implantation into the PMOS active area 232 of a high work function element is combined with the already deposited low work function metal alloy, such that the resultant PMOS work function (after FUSI processing) remains high (e.g., about 5 eV). In some embodiments, the masked ion implantation into the PMOS active area 232 is performed prior to the low work function metal alloy deposition. In alternative embodiments, a high work function metal alloy is deposited over both the PMOS active area 232 and the NMOS active area 233, the high work function metal alloy is patterned and etched from NMOS active area 233, and a low work function metal alloy is deposited over the NMOS active area 233. In other alternative embodiments, a low work function metal alloy is deposited over both the PMOS active area 232 and the NMOS active area 233, the low work function metal alloy is patterned and etched from PMOS active area 232, and a high work function metal alloy is deposited over the PMOS active area 232.

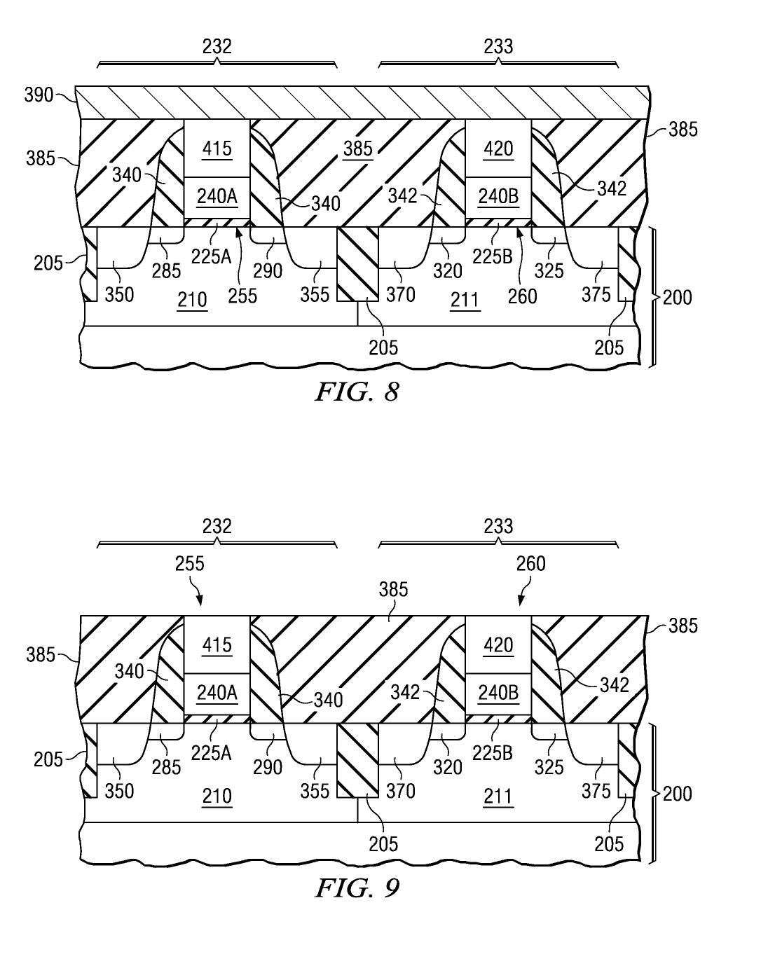

Referring to FIG. 8, after the high or low work function-setting dopant or dopants have been introduced (whether by a masked ion implantation, a blanket ion implantation, an alloy deposition, or some combination thereof), an anneal is performed to induce a reaction between the metal layer 390 and the polysilicon layers 245A, 245B (FIG. 7). The reaction between the metal layer 390 and the polysilicon layers 245A, 245B (FIG. 7) creates a fully silicided layer 415 in the PMOS active area 232 and a fully silicided layer 420 in the NMOS active area 233. In some embodiments, the silicide layers 415, 420 comprise nickel silicide (NiSi) layers. In other embodiments, the silicide layers 415, 420 comprise silicon-rich nickel silicide layers (NiSi₂). In yet other embodiments, the silicide layers 415, 420 comprise alternative silicide compositions such as NiSiₓ, where x is a positive integer or positive rational number and the silicide can be either metal-rich (x<1) or silicon-rich (x>1). For purposes of this discussion, it can be assumed that the high or low work function-setting dopants are substantially within each of the polysilicon layers 245A, 245B (FIG. 7). In particular, during the reaction of the metal layer 390 with each of the polysilicon layers 245A, 245B (FIG. 7), metal (e.g., nickel) of the metal layer 390 diffuses into each of the polysilicon layers 245A, 245B (FIG. 7), reacts with the polysilicon layers 245A, 245B (FIG. 7), and the work function-setting dopants within each of the polysilicon layers 245A, 245B (FIG. 7) diffuse towards each of the silicide layers 240A, 240B, ahead of the propagating metal layer 390/polysilicon layer (245A or 245B, FIG. 7) reaction front. Thus, the work function-setting dopants are “pushed” (i.e., transported or delivered) towards the silicide layers 240A, 240B and diffuse to the interface between the gate dielectric (e.g., the dielectric layer 225A or the dielectric layer 225B) and the overlying electrode (e.g., the silicide layer 240A or the silicide layer 240B). In particular, when the work function-setting dopants reach the interface of the polysilicon layer 245A/silicide layer 240A (or likewise the interface of the polysilicon layer 245B/silicide layer 240B) (FIG. 7), the work function-setting dopants diffuse along grain boundaries of each of the silicide layers 240A, 240B such that work function-setting dopants are effectively delivered to the interface of the silicide layer 240A/dielectric layer 225A (or likewise the interface of the silicide layer 240B/dielectric layer 225B). The work function for each of the PMOS gate electrode (silicide layer 240A) and the NMOS gate electrode (silicide layer 240B) is thus set to the desired value once the work function-setting dopants are delivered to the respective interface.

In the embodiments disclosed herein, the thermal budget used to react the metal layer 390 to each of the polysilicon layers 245A, 245B, is sufficient to deliver the work function-setting dopants to the silicide layer 240A/dielectric layer 225A interface and the silicide layer 240B/dielectric layer 225B interface, where the presence of the silicide layers 240A, 240B provide flexibility in the choice of thermal budget used (as discussed below). As shown in FIG. 9, any of the metal layer 390 that remains after the silicidation of the polysilicon layers 245A, 245B, is removed (e.g., by way of a wet chemical etch). Thereafter, other CMOS processing may follow (e.g., the oxide layer 385 is removed, and interlayer dielectric and metallization layers can be formed).

In other embodiments, the silicidation of the polysilicon layers 245A, 245B is performed according to an alternative method, for example, using a two anneal process. In particular, a first anneal is performed that does not fully react all the polysilicon of the polysilicon layers 245A, 245B. Any remaining metal of the metal layer 390 is then removed, and a second anneal is performed to complete the reaction of the polysilicon layer 245A, 245B (FIG. 7 to arrive at FIG. 9). Removing residual metal of the metal layer 390 prior to completing the silicidation reaction is performed to avoid, for example, a nickel-rich phase of nickel silicide (e.g., Ni₂Si) in the case that the nickel-rich phase is not desired. Also, because NMOS polysilicon often silicides faster than PMOS polysilicon, the two anneal process can be used to maintain control over the silicidation process. In particular, the first anneal can be used to introduce just enough metal into each of the polysilicon layers 245A, 245B to fully react each of the polysilicon layers 245A, 245B during a second anneal, without performing the full silicidation during the first anneal. Thereafter, any remaining metal of the metal layer 390 is removed, and the second anneal is performed to complete the reaction and fully silicide each of the polysilicon layers 245A, 245B (FIG. 7 to arrive at FIG. 9).

The thermal budget used to induce the reaction between the metal layer 390 and the polysilicon layers 245A, 245B (FIG. 7) is low as compared to, for example, the thermal budget used for activation of the source and drain regions (350, 355, 370, 375). Therefore, the full silicidation of the polysilicon layers 245A, 245B (FIG. 7) can be performed after higher thermal budget processing is complete. However, in the various embodiments, the silicide layers 240A, 240B provide flexibility to use higher thermal budget processes inasmuch as the silicide layers 240A, 240B protect the dielectric layers 225A, 225B (and thus the interfaces of the silicide layer 240A/dielectric layer 225A and the silicide layer 240B/dielectric layer 225B where the PMOS and NMOS gate electrode work functions are set). The ability to use a higher thermal budget process, for example, provides more robust silicide layers 415, 420 that are substantially free of pockets of incomplete silicidation. However, even in some exemplary embodiments where the silicide layers 415, 420 contain pockets of incomplete silicidation, the presence of the silicide layers 240A, 240B substantially mitigate any adverse effect the pockets of incomplete silicidation would otherwise have on transistor operation (e.g., degraded inversion layer thickness and corresponding degraded drive current). Also, the silicide layers 240A, 240B protect against punch-through defects, where metal (e.g., nickel) diffuses through a dielectric layer and destroys transistor operation.

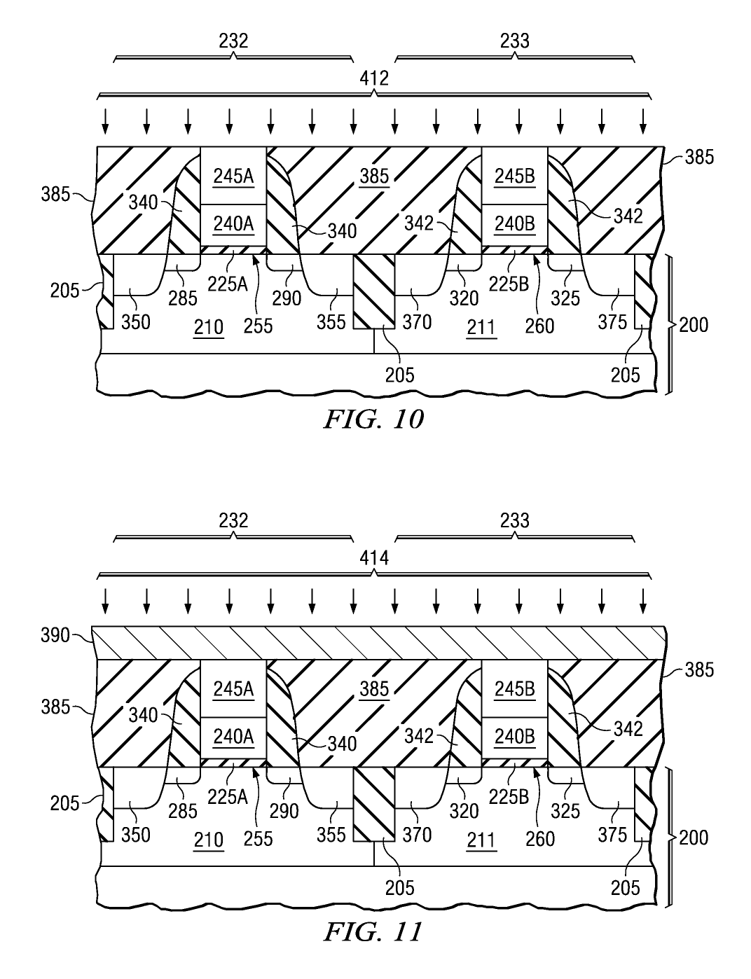

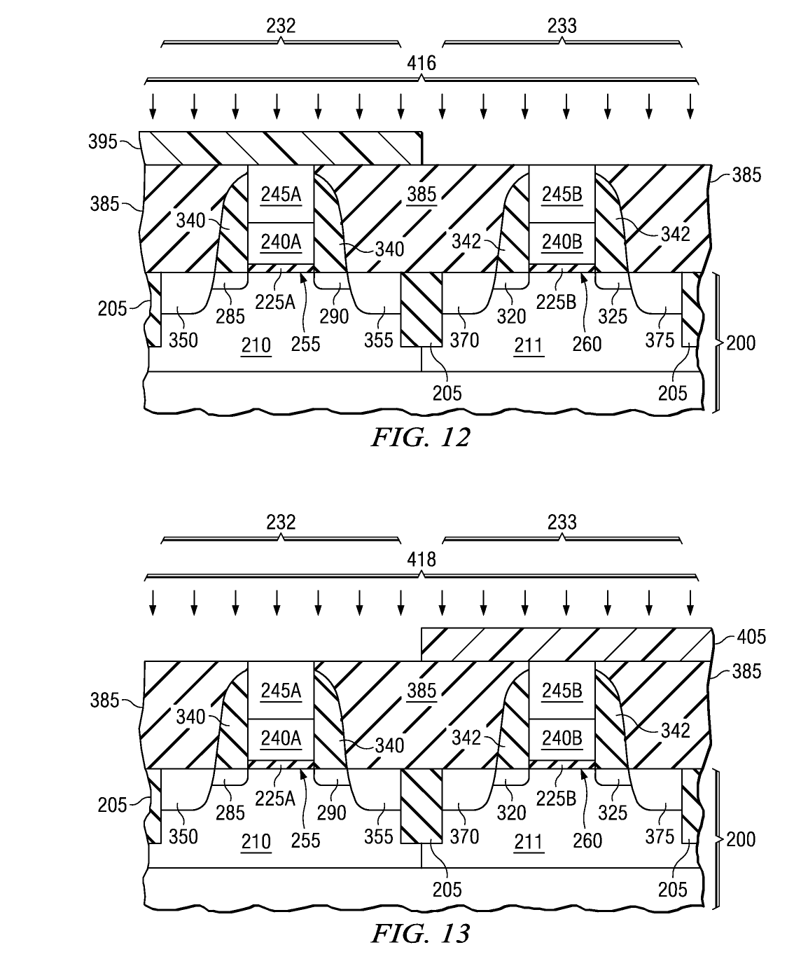

FIGS. 10-13 illustrate variations to the ion implantation of the work function-setting dopants. Specifically, FIG. 10 shows a blanket ion implantation 412 performed into both the PMOS active area 232 and the NMOS active area 233 prior to forming the metal layer 390 (FIG. 6). In some embodiments, the ion implantation 412 is equivalent to the ion implantation 400 (FIG. 6), where the ion implantation 412 comprises an N-type work function-setting dopant comprising a low work function element. In other embodiments, the ion implantation 412 is equivalent to the ion implantation 410 (FIG. 7), where the ion implantation 412 comprises a P-type work function-setting dopant comprising a high work function element. FIG. 11 shows a blanket ion implantation 414 performed into both the PMOS active area 232 and the NMOS active area after forming the metal layer 390. In some embodiments, the ion implantation 414 is equivalent to the ion implantation 400 (FIG. 6), where the ion implantation 414 comprises an N-type work function-setting dopant comprising a low work function element. In other embodiments, the ion implantation 414 is equivalent to the ion implantation 410 (FIG. 7), where the ion implantation 414 comprises a P-type work function-setting dopant comprising a high work function element. FIG. 12 shows an ion implantation 416 performed into the NMOS active area 233 (while masking the PMOS active area 232) prior to forming the metal layer 390 (FIG. 6). The ion implantation 416 is equivalent to the ion implantation 400 (FIG. 6), where the ion implantation 416 comprises an N-type work function-setting dopant comprising a low work function element. FIG. 13 shows an ion implantation 418 performed into the PMOS active area 232 (while masking the NMOS active area 233) prior to forming the metal layer 390 (FIG. 6). The ion implantation 418 is equivalent to the ion implantation 410 (FIG. 7), where the ion implantation 418 comprises a P-type work function-setting dopant comprising a high work function element.

The above discussion is meant to be illustrative of the principles and various embodiments of the present invention. Numerous variations and modifications will become apparent to those skilled in the art once the above disclosure is fully appreciated. For example, after the silicide layers 415, 420 are formed, another anneal may be performed in order to change the phase of the silicide layers 415, 420 into a low-resistance phase. In addition, the thermal budget used to induce the reaction between the metal layer 390 and the polysilicon layers 245A, 245B can be varied in order to form silicide layers 415, 420 having one of a plurality of phases. Also, unless otherwise indicated, any one or more of the layers set forth herein can be formed in any number of suitable ways (e.g., with spin-on techniques, sputtering techniques (e.g., magnetron and/or ion beam sputtering), thermal growth techniques, deposition techniques such as chemical vapor deposition (CVD), physical vapor deposition (PVD) and/or plasma enhanced chemical vapor deposition (PECVD), or atomic layer deposition (ALD)). And, unless otherwise indicated, any one or more of the layers can be patterned in any suitable manner (e.g., via lithographic and/or etching techniques). It is intended that the following claims be interpreted to embrace all such variations and modifications.

What is claimed is:

1. A method comprising:
forming a gate stack over a semiconductor substrate, the gate stack comprising a dielectric layer, a silicide layer on the dielectric layer that defines a metal-dielectric layer interface, and a polysilicon layer on the silicide layer;
depositing a metal layer over the gate stack;
annealing to induce a reaction between the polysilicon layer and the metal layer; and
delivering a work function-setting dopant to the metal-dielectric layer interface by way of the reaction.

2. The method according to claim 1 further comprising protecting the dielectric layer from the metal layer by way of the silicide layer.

3. The method according to claim 1 wherein delivering the work function-setting dopant further comprises delivering a low work function element comprising one or more selected from the group consisting of: titanium (Ti); zirconium (Zr); hafnium (Hf); tantalum (Ta); lanthanum (La); yttrium (Y); cerium (Ce); praseodymium (Pr); neodymium (Nd); promethium (Pm); samarium (Sm); europium (Eu); gadolinium (Gd); terbium (Tb); dysprosium (Dy); holmium (Ho); erbium (Er); thulium (Tm); ytterbium (Yb); phosphorous (P); arsenic (As); and antimony (Sb).

4. The method according to claim 1 wherein delivering the work function-setting dopant further comprises delivering a high work function element comprising one or more selected from the group consisting of: platinum (Pt); ruthenium (Ru); rhenium (Re); rhodium (Rh); and iridium (Ir).

5. The method according to claim 1 wherein forming the gate stack further comprises forming the gate stack wherein the silicide layer comprises one or more selected from the group consisting of: tungsten (W); tungsten silicide (WSi₂); molybdenum (Mo); molybdenum disilicide (MoSi₂); a W/WSi₂ stack; a Mo/MoSi₂ stack; and crystalline TaN.

6. The method according to claim 1 further comprising performing an ion implantation into a PMOS active area.

7. The method according to claim 1 further comprising performing an ion implantation into an NMOS active area.

8. The method according to claim 1 further comprising performing a blanket ion implantation into a PMOS active area and into an NMOS active area.

9. The method according to claim 3 further comprising, prior to depositing the metal layer over the gate stack, performing an ion implantation of the low work function element into the polysilicon layer.

10. The method according to claim 4 further comprising, prior to depositing the metal layer over the gate stack, performing an ion implantation of the high work function element into the polysilicon layer.

11. The method according to claim 3 further comprising, after depositing the metal layer over the gate stack, performing an ion implantation of the low work function element into the metal layer.

12. The method according to claim 4 further comprising, after depositing the metal layer over the gate stack, performing an ion implantation of the high work function element into the metal layer.

13. The method according to claim 1 wherein depositing the metal layer further comprises depositing a metal alloy comprising a low work function element.

14. The method according to claim 1 wherein depositing the metal layer further comprises depositing a metal alloy comprising a high work function element.

15. The method according to claim 13 further comprising performing an ion implantation of the work function-setting dopant.

16. The method according to claim 14 further comprising performing an ion implantation of the work function setting dopant.

17. The method according to claim 1 wherein depositing the metal layer further comprises depositing a layer of nickel.

18. The method according to claim 17 wherein annealing to induce the reaction further comprises annealing to induce the reaction, wherein the reaction forms a nickel silicide (NiSi) layer.

19. The method according to claim 17 wherein annealing to induce the reaction further comprises annealing to induce the reaction, wherein the reaction forms a NiSiₓ layer, and wherein x comprises one selected from the group consisting of: a positive integer; and a positive rational number.

20. A method comprising:
forming a PMOS gate stack over a semiconductor substrate, the PMOS gate stack comprising a first dielectric layer, a first silicide layer on the first dielectric layer that defines a first metal-dielectric layer interface, and a first polysilicon layer on the first silicide layer;
forming an NMOS gate stack over a semiconductor substrate, the NMOS gate stack comprising a second dielectric layer, a second silicide layer on the second dielectric layer that defines a second metal-dielectric layer interface, and a second polysilicon layer on the second silicide layer;
depositing a metal layer over both the PMOS gate stack and the NMOS gate stack;
annealing to induce a reaction between the first polysilicon layer and the metal layer and between the second polysilicon layer and the metal layer;
delivering a first work function-setting dopant to the first metal-dielectric layer interface by way of the reaction; and
delivering a second work function-setting dopant to the second metal-dielectric layer interface by way of the reaction.

21. A semiconductor device comprising:
a substrate comprising a P-type active area;
an isolation structure abutting the P-type active area;
an N-type active area abutting the isolation structure;
a PMOS gate stack on the P-type active area, the PMOS gate stack comprising a first dielectric layer, a first silicide layer on the first dielectric layer that defines a first metal-dielectric layer interface, and a first polysilicon layer on the first silicide layer;
an NMOS gate stack on the N-type active area, the NMOS gate stack comprising a second dielectric layer, a second silicide layer on the second dielectric layer that defines a second metal-dielectric layer interface, and a second polysilicon layer on the second silicide layer;
a metal layer on the PMOS gate stack and on the NMOS gate stack, wherein the metal layer is configured to react with each of the first polysilicon layer and the second polysilicon layer;
a first work function-setting dopant within the PMOS gate stack; and
a second work function-setting dopant within the NMOS gate stack;
wherein the first work function-setting dopant is delivered to first metal-dielectric layer interface by way of the reaction; and
wherein the second work function-setting dopant is delivered to the second metal-dielectric layer interface by way of the reaction.

22. The semiconductor device according to claim 21 wherein the first dielectric layer is protected from the metal layer by way of the first silicide layer, and wherein the second dielectric layer is protected from the metal layer by way of the second silicide layer.

23. The semiconductor device according to claim 21 wherein the first work function-setting dopant comprises a high work function element comprising one or more selected from the group consisting of: platinum (Pt); ruthenium (Ru); rhenium (Re); rhodium (Rh); and iridium (Ir).

24. The semiconductor device according to claim 21 wherein the second work function-setting dopant comprises a low work function element comprising one or more selected from the group consisting of: titanium (Ti); zirconium (Zr); hafnium (Hf); tantalum (Ta); lanthanum (La); yttrium (Y); cerium (Ce); praseodymium (Pr); neodymium (Nd); promethium (Pm); samarium (Sm); europium (Eu); gadolinium (Gd); terbium (Tb); dysprosium (Dy); holmium (Ho); erbium (Er); thulium (Tm); ytterbium (Yb); phosphorous (P); arsenic (As); and antimony (Sb).

25. The semiconductor device according to claim 21 wherein each of the first silicide layer and the second silicide layer comprises one or more selected from the group consisting of: tungsten (W); tungsten silicide (WSi₂); molybdenum (Mo); molybdenum disilicide (MoSi₂); a W/WSi₂ stack; a Mo/MoSi₂ stack; and crystalline TaN.
